(19) United States
(12) Patent Application Publication
(10) Pub. No.: US 2007/0205459 A1
(43) Pub. Date: Sep. 6, 2007

(54) Nonvolatile memory devices and methods of forming the same

(76) Inventors: Eun-Suk Cho, Suwon-si (KR); Dong-Gun Park, Seongnam-si (KR); Choong-Ho Lee, Seongnam-si (KR); Jong-Jin Lee, Seongnam-si (KR); Jeong-Dong Choe, Anyang-si (KR)

Correspondence Address: LEE & MORSE, P.C., 3141 FAIRVIEW PARK DRIVE, SUITE 500, FALLS CHURCH, VA, 22042, US

(21) Appl. No.: 11/653,359

(22) Filed: Jan. 16, 2007

(30) Foreign Application Priority Data
Mar. 2, 2006 (KR) 2006-0020021

(51) Int. Cl. H01L 29/788

(52) U.S. Cl. 257/321

(57) ABSTRACT

A nonvolatile memory device includes a semiconductor pin including a first semiconductor pattern, a second semiconductor pattern on the first semiconductor pattern, and a third semiconductor pattern, disposed between the first semiconductor pattern and the second semiconductor pattern, connecting the first semiconductor pattern and the second semiconductor pattern, a charge storage layer on the second semiconductor pattern with a tunneling insulation layer interposed therebetween, and a gate electrode on the charge storage layer with a blocking insulation layer interposed therebetween, wherein a width of the second semiconductor pattern is greater than a width of the third semiconductor pattern.

### BACKGROUND OF THE INVENTION

1. Field of the Invention

The present invention relates to semiconductor devices and methods of forming the same. More particularly, the invention relates to nonvolatile memory devices and methods of forming the same.

2. Description of the Related Art

Generally, semiconductor memory devices can be classified into volatile memory devices and nonvolatile memory devices. The volatile memory devices lose data stored therein when power supply is stopped, whereas nonvolatile memory devices maintain data stored therein even when power supply is stopped.

Flash memory devices are one kind of nonvolatile memory device. A flash memory device is a highly-integrated nonvolatile memory device that is developed to have the advantages of an erasable programmable read only memory (EPROM) and the advantages of an electrically erasable programmable read only memory (EEPROM).

Flash memory devices may be classified into floating gate type flash memory devices and charge trap type flash memory devices, depending on the kind of data storage layer included in a unit cell thereof. Also, flash memory devices may be classified into stacked gate type flash memory devices and split gate type flash memory devices, depending on a unit cell structure thereof.

Unlike floating gate type flash memory devices that store charge(s) in a polysilicon layer, charge trap type flash memory devices store charge(s) in a trap site formed in a nonconductive charge trap layer. A memory cell of the charge trap type memory device generally has a stacked gate structure including a tunnel oxide layer, a silicon nitride layer serving as a charge trap layer, a blocking oxide layer and a conductive layer sequentially formed on a silicon substrate.

As channel widths are decreased to enable high-integration, a threshold voltage of the memory cell may increase. As a result of such threshold voltage differences, when the memory cell operates, an error may occur and reliability of the memory device may be reduced. Memory devices that may be highly-integrated while substantially maintaining their operational reliability are desired.

### SUMMARY OF THE INVENTION

The present invention is therefore directed to semiconductor devices and methods of manufacturing thereof, which substantially overcome one or more of the problems due to the limitations and disadvantages of the related art.

It is therefore a feature of an embodiment of the present invention to provide a highly integrateable nonvolatile memory device having enhanced operation characteristics and reliability.

It is therefore a separate feature of an embodiment of the present invention to provide a method of forming a highly integrateable nonvolatile memory device having enhanced operation characteristics and reliability.

At least one of the above another features and advantages of the present invention may be realized by providing a nonvolatile memory device, including a semiconductor pin including a first semiconductor pattern, a second semiconductor pattern on the first semiconductor pattern, and a third semiconductor pattern, disposed between the first semiconductor pattern and the second semiconductor pattern, connecting the first semiconductor pattern and the second semiconductor pattern, a charge storage layer on the second semiconductor pattern with a tunneling insulation layer interposed therebetween, and a gate electrode on the charge storage layer with a blocking insulation layer interposed therebetween, wherein a width of the second semiconductor pattern is greater than a width of the third semiconductor pattern.

The first semiconductor pattern may be a portion of a semiconductor substrate on which the nonvolatile memory device is formed and/or is connected to and/or extends from the semiconductor substrate. The charge storage layer may include nanocrystals. A width of the first semiconductor pattern may be greater than the width of the second semiconductor pattern along a direction along which the gate electrode extends. The second semiconductor pattern may have a circular or elliptical cross-sectional shape. The second semiconductor pattern may have a cylindrical shape and may extend in a direction crossing the direction along which the gate electrode extends.

The nonvolatile memory device may further include channel-region and source/drain regions, wherein the channel region and the source/drain regions may be disposed in the second semiconductor pattern. Other than a portion of the second semiconductor pattern that contacts the third semiconductor pattern, the second semiconductor pattern may be substantially surrounded by a gate insulating layer. The nonvolatile memory device may further include a device-isolation layer pattern disposed at both sides of the semiconductor pin, the device-isolation layer defining the semiconductor pin as an active region, wherein an upper surface of the device-isolation layer pattern may be disposed under the third semiconductor pattern.

At least one of the above another features and advantages of the present invention may be separately realized by providing a method for forming a nonvolatile memory device, the method including forming a semiconductor pin including a first semiconductor pattern, a second semiconductor pattern on the first semiconductor pattern, and a third semiconductor pattern, disposed between the first semiconductor pattern and the second semiconductor pattern, connecting the first semiconductor pattern and second semiconductor pattern, forming a tunneling insulation layer on the second semiconductor pattern, forming a charge storage layer on the tunneling insulation layer, forming a blocking insulation layer on the charge storage layer, and forming a gate electrode extending on the blocking insulation layer in a direction crossing a direction along which the semiconductor pin extends, wherein a width of the second semiconductor pattern is greater than a width of the third semiconductor pattern.

The width of the first semiconductor patter maybe greater than the width of the second semiconductor pattern along a direction in which the gate electrode extends. Forming the semiconductor pin may include forming a preliminary semiconductor pin connected to the semiconductor substrate and having a substantially uniform width, forming a device-isolation layer pattern disposed on sides of the preliminary semiconductor pin, a portion of the preliminary semiconductor pin protruding beyond an upper surface of the device-isolation layer pattern, forming a spacer on a protruding portion of an upper sidewall of the preliminary semiconductor pin, recessing the device-isolation layer pattern to expose a portion of the preliminary semiconductor pin, and removing a portion of the exposed preliminary semiconductor pin to reduce a width thereof.

Reducing the width of the exposed preliminary semiconductor pin may include performing an oxidation process on the exposed preliminary semiconductor pin to form a sacrificial oxide layer reducing the width of the preliminary semiconductor pin, and performing an isotropic etching process to remove the sacrificial oxide layer. The oxidation process may be a thermal oxidation process, and the sacrificial oxide layer may be a thermal oxide layer. The method may further include removing the spacer and performing an isotropic etching process after removing the spacer to form the second semiconductor pattern having a cylindrical shape. Forming the preliminary semiconductor pin may include forming a mask pattern on semiconductor substrate, the mask pattern corresponding to a region where the semiconductor pin is to be formed, etching the semiconductor substrate using the mask pattern as an etch mask to form a trench, and forming a device-isolation layer filling the trench. The spacer may be formed of a material having an etch selectivity with regard to the device-isolation layer. The method may further include performing a channel ion implantation process on the second semiconductor pattern before forming the tunneling insulation layer. Forming the charge storage layer may include forming nanocrystals on the tunneling insulation layer. The method may further include performing an ion implantation process to form a source/drain region in the second semiconductor pattern after forming the gate electrode.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1A illustrates a perspective view of a nonvolatile memory device according to an exemplary embodiment of the present invention, and FIGS. 1B and 1C illustrate cross-sectional views of the nonvolatile memory device illustrated in FIG. 1A, taken along lines A-A′ and B-B′ of FIG. 1A, respectively; and

FIGS. 2 through 15 illustrate perspective views of stages in a method of forming a nonvolatile memory device according to an exemplary embodiment of the present invention.

### DETAILED DESCRIPTION OF THE INVENTION

Korean Patent Application No. 2006-0020021, filed on Mar. 2, 2006, in the Korean Intellectual Property Office, and entitled: “Nonvolatile Memory Device and Method of Forming the Same,” is incorporated by reference herein in its entirety.

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art.

It will be understood that, although the terms, first, second, and the like may be used herein to describe various regions, layers, and the like, these regions, layers, and the likes should not be limited by these terms. These terms are only used to distinguish one region, layer, and the like from another region, layer, and the like. It will also be understood that when a layer is referred to as being “on” another layer or substrate, it can be directly on the other layer or substrate, or intervening layers may also be present. In the drawings, the thicknesses of layers and regions may be exaggerated for clarity. Like reference numerals refer to like elements throughout the specification. Embodiments of the present invention exemplarily illustrate charge trap type flash memory devices. Of course, these are only examples and should not be construed to limit the present invention. The present invention can be applied to other type of flash memory devices and further to nonvolatile memory devices other than the flash memory devices.

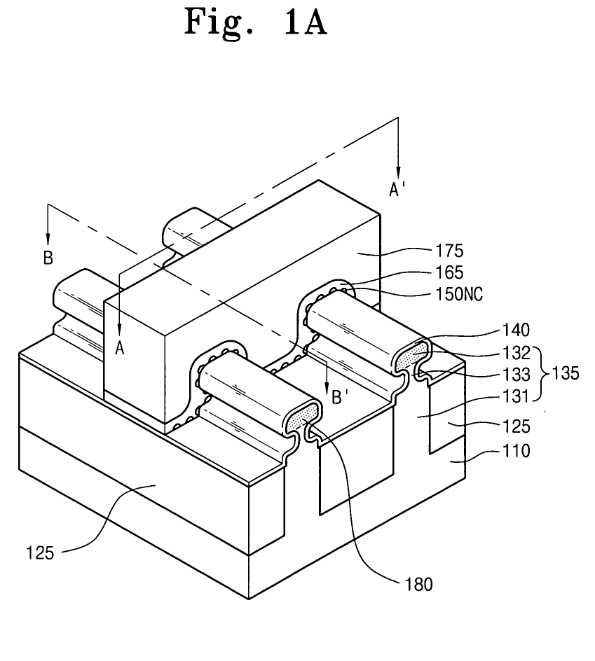

FIG. 1A illustrates a perspective view of a nonvolatile memory device according to an exemplary embodiment of the present invention, and FIGS. 1B and 1C illustrate cross-sectional views of the nonvolatile memory device illustrated in FIG. 1A, taken along lines A-A′ and B-B′ of FIG. 1A, respectively.

Referring to FIGS. 1A, 1B and 1C, a semiconductor pin 135 may be disposed on a semiconductor substrate 110. The semiconductor pin 135 may correspond to an active region of the semiconductor substrate 110, and may be defined by a device isolation layer pattern 125. The device isolation pattern 125 may be formed at predetermined region(s) of the semiconductor substrate 110.

The semiconductor pin 135 may include a first semiconductor pattern 131, a second semiconductor pattern 132, and a third semiconductor pattern 133. The second semiconductor pattern 132 may be disposed on the first semiconductor pattern 131. The first semiconductor pattern may contact the semiconductor substrate 110 and/or may correspond to a portion of the semiconductor substrate 110, i.e., may continuously extend from the semiconductor substrate 110. The first semiconductor pattern 131 and the second semiconductor pattern 132 may be connected to each other by the third semiconductor pattern 133. An upper surface of the device isolation pattern 125 may be lower than the second semiconductor pattern 132 and the third semiconductor pattern 133. That is, the second semiconductor pattern 132 and the third semiconductor pattern 133 may protrude beyond the upper surface of the device isolation pattern 125. More particularly, an upper portion of the semiconductor pin 135, which may correspond to the second semiconductor pattern 132 and the third semiconductor pattern 133, may protrude between the device isolation patterns 125. In some embodiments, an upper portion of the first semiconductor pattern 131 may also protrude beyond the upper surface of the device isolation layer 125.

Referring to FIG. 1B, the first, second and third semiconductor patterns 131, 132, 133 may have different widths. A width d1 of the first semiconductor pattern 131 may be greater than a width d2 of the second semiconductor pattern 132, and the width d2 of the second semiconductor pattern 132 may be greater than a width d3 of the third semiconductor pattern 133.

The second semiconductor pattern 132 may have a cylinder-like shape extending in a first direction. The first direction may correspond to a direction along which the semiconductor pin 135 extends or a direction along which the device isolation layer 125 extends. The second semiconductor pattern 132 may have a rounded, e.g., circular, elliptical, etc., cross-sectional shape, taken along a second direction crossing the first direction, e.g., along a direction perpendicular to the first direction. By making an edge of the second semiconductor pattern 132 rounded, it is possible to reduce or eliminate parasitic capacitance, as discussed in more detail below.

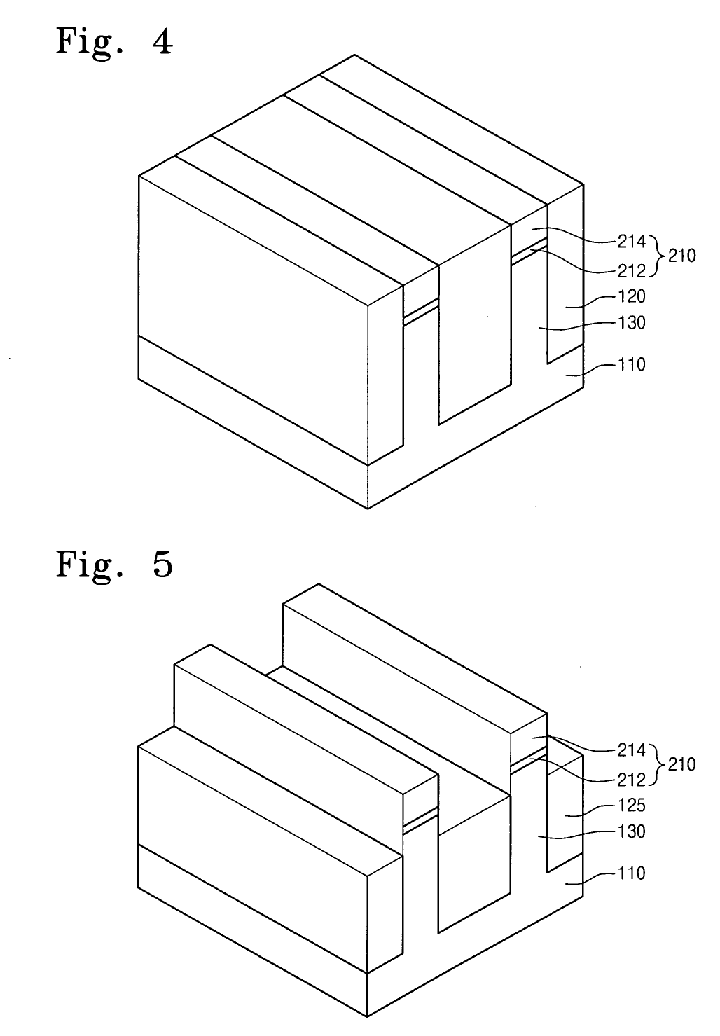

A tunneling insulation layer 140 may cover the semiconductor pin 135 protruding between the device isolation layer patterns 125. The tunneling insulation layer 140 may be conformally formed on a surface, e.g., an entire surface, of the semiconductor substrate 110. The term “conformally” corresponds to a layer formed with a uniform thickness or substantially uniform thickness along a profile of an underlying layer or structure. In some embodiments of the invention, the second semiconductor pattern 132 may be covered by the tunneling insulation layer 140. More particularly, the second semiconductor pattern 132 may be surrounded by the tunneling insulation layer 140 except for a portion thereof contacting the underlying third semiconductor pattern 133. The tunneling insulation layer 140 may be formed of a material layer that can form a tunnel through which charges can move when a high electric field is applied between a gate electrode 175 and a channel region 185 (see FIG. 4C) of the substrate 110. For example, the tunneling insulation layer 140 may include and/or be a silicon oxide layer.

A charge storage layer 150 may be disposed on the tunneling insulation layer 140. The charge storage layer 150 may include nanocrystal(s) 150NC as a charge storage element. The nanocrystal 150NC may include, e.g., nitride, oxide, silicon, silicon-germanium and/or metal material. Because the respective nanocrystals 150NC may be spaced apart from each other by different distances, at least some of the nanocrystals 150NC may be insulated from one another.

A blocking insulation layer 165 may be disposed on the charge storage layer 150. In such embodiments, because the nanocrystal 150NC may be used as the charge storage element, the blocking insulation layer 165 may contact the tunneling insulation layer 140 between the nanocrystals 150NC. In such embodiments, the charge storage layer 150 may include the nanocrystals 150NC and the blocking insulation layer 165 may occupy spaces between the nanocrystals 150NC. In such cases, the nanocrystals 150NC may be insulated by the blocking insulation layer 165 filling spaces therebetween. The blocking insulation layer 165 may include and/or be an oxide layer. For example, in some embodiments, the blocking insulation layer 165 may be made of an insulating material having a high dielectric constant, e.g., aluminum oxide (Al₂O₃), hafnium oxide (HfO), hafnium aluminum oxide (HfAlO), hafnium silicon oxide (HfSiO), or the like.

A gate electrode 175 may be disposed on the blocking insulation layer 165. The gate electrode 175 may extend in the second direction crossing the first direction. As discussed above, the first direction may be perpendicular to the second direction. Each of the gate electrodes 175 extending along the second direction may correspond to a word line. The gate electrode 175 may include a conductive material, e.g., doped polysilicon and/or metal.

Impurity regions 180 (or junction regions) corresponding to source/drain regions may be formed in the second semiconductor pattern 132 at both sides of the gate electrode 175. The channel region 185 may correspond to a portion of the second semiconductor pattern 132 between the impurity regions 180.

A memory device may be an n-channel device or p-channel device depending on a conductivity type of the semiconductor substrate 110 and the impurity regions 180. For example, if the semiconductor substrate 110 is p-type and the impurity regions 180 are n-type, the memory device may be an n-channel memory device, whereas if the semiconductor substrate 110 is n-type and the impurity regions 180 are p-type, the memory device may be a p-channel memory device.

When an appropriate voltage is applied to the semiconductor substrate 110 and the gate electrode 175, charges may tunnel through the tunneling insulation layer 140 (or tunnel through a potential barrier of the tunneling insulation layer 140) and may be trapped by the nanocrystals 150NC of the charge storage layer 150. Because the nanocrystals 150NC may be insulated from one another, the charges trapped by the nanocrystals 150NC may not move or diffuse. The blocking insulation layer 165 may insulate the nanocrystals 150NC from the gate electrode 175 and, as discussed above, may also suppress and/or prevent the charges from moving between the nanocrystals 150NC and the gate electrode 175. A thicknesses of the tunneling insulation layer 140, the charge storage layer 150 (nanocrystals 150NC) and the blocking insulation layer 165 may be set and/or determined according to a bias condition and/or a program/erase method being employed. The charges may appear based on a combination of voltages applied to the substrate 110, the gate electrode 175 and the impurity region 180, and the charges may be, e.g., electrons, thermal electrons, thermal holes and holes, etc.

In embodiments of the invention, e.g., the exemplary embodiment illustrated in FIGS. 1A through 1C, because the second semiconductor pattern 132 where the channel region 185 may be disposed to have a three dimensional structure, i.e., protruding structure, although the width d2 of the second semiconductor pattern 132 may be relatively narrow, i.e., although the memory device may be highly integrated, the channel width may be maintained over a predetermined length, so that the threshold voltages of the cells may have a relatively narrow distribution. The channel width may correspond to a length of a contact portion between the second semiconductor pin 132 and the tunneling insulation layer 140.

In embodiments of the invention, a circumferential length of the second semiconductor pattern 132 may be decreased, e.g., by adjusting a size of the second semiconductor pattern 132 during the formation process. Thus, in embodiments of the invention, a threshold voltage may be increased as a result of a bottleneck effect. More particularly, although the memory device is highly integrated, a threshold voltage with a desired size and distribution can be obtained by properly adjusting the size of the second semiconductor pattern 132.

Also, in embodiments of the invention, because the tunneling insulation layer 140 may overlap the channel region 185, the channel may be better controlled by the gate electrode 175.

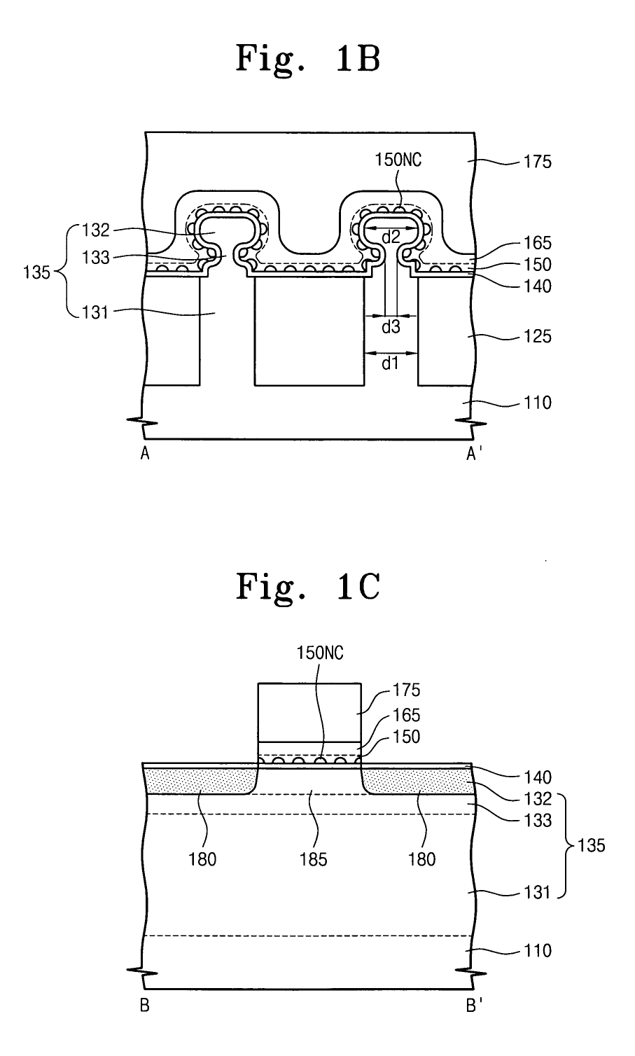

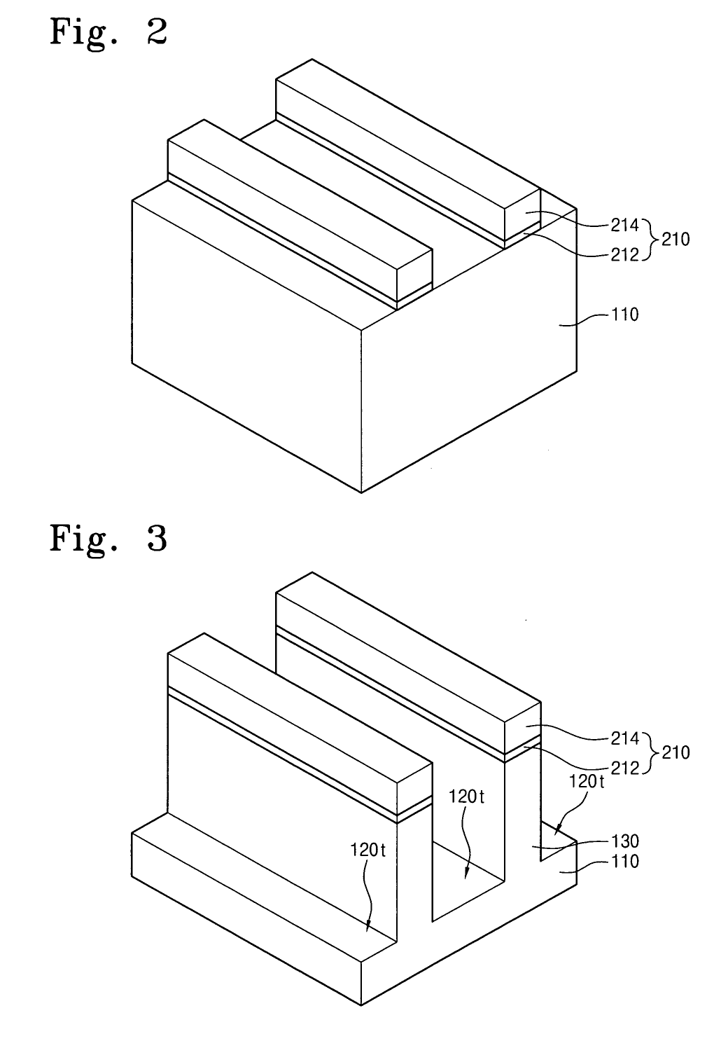

FIGS. 2 through 15 illustrate perspective views of stages in a method of forming a nonvolatile memory device according to an exemplary embodiment of the present invention.

Referring to FIG. 2, a mask 210 may be formed on a semiconductor substrate 110. In some embodiments, the semiconductor substrate 110 may be a bulk silicon substrate, e.g., a single crystal silicon substrate formed using known method(s). However, a variety of substrates may be employed, including, e.g., a silicon on insulator (SOI) substrate in which a silicon layer is located on an insulating layer.

The mask 210 may include a plurality of layers, which may be stacked on each other. For example, the mask 210 may include an oxide layer 212 and a nitride layer 214. The oxide layer 212 and the nitride layer 214 may be formed using known thin film forming process(es). For example, the oxide layer 212 may be formed using a thermal oxidation process, and the nitride layer 214 may be formed through a deposition process.

Referring to FIG. 3, an etch process using the mask 210 as an etch mask may be performed to form trench(es) 120t and a preliminary semiconductor pin 130. The preliminary semiconductor pin 130 may correspond to an active region and the trench 120t may correspond to a device isolation region. In some embodiments, an anisotropic etching method may be used to form the trench(es) 120t.

Referring to FIG. 4, the trench(es) 120t may be filled with a preliminary device isolation layer (not shown), and a planarizing process may be performed to expose an upper surface of the mask 210 and to form a device isolation layer 120.

The device isolation layer 120 may include, e.g., silicon oxide, and may be formed using known thin film forming process(es). Before the device isolation layer 120 is formed, a thermal oxide layer (not shown) for curing etch damage that may have occurred during etching of the semiconductor substrate 110 may be formed on an inner wall of the trench(es) 120t. Also, a liner layer (not shown) for suppressing and/or preventing impurity(ies) from penetrating into the active region may be further formed on the thermal oxide layer.

In some embodiments of the invention, a chemical mechanical polishing (CMP) using a slurry having an etch selectivity with regard to the trench mask 210 may be used for the above mentioned planarizing process.

Referring to FIG. 5, an etch process may be performed to remove an upper portion of the device isolation layer 120 and form a device isolation pattern 125. During the etch process, the device isolation layer 120 may be recessed by an anisotropic etch using an etch recipe having an etch selectivity with regard to the mask 210.

As a result of the above etch process, the preliminary semiconductor pin 130 may at least partially protrude between the device isolation layer patterns 125 relative to the upper surface of the device isolation layer 120. In such cases, upper sidewalls of the device isolation layer patterns 125 may be exposed.

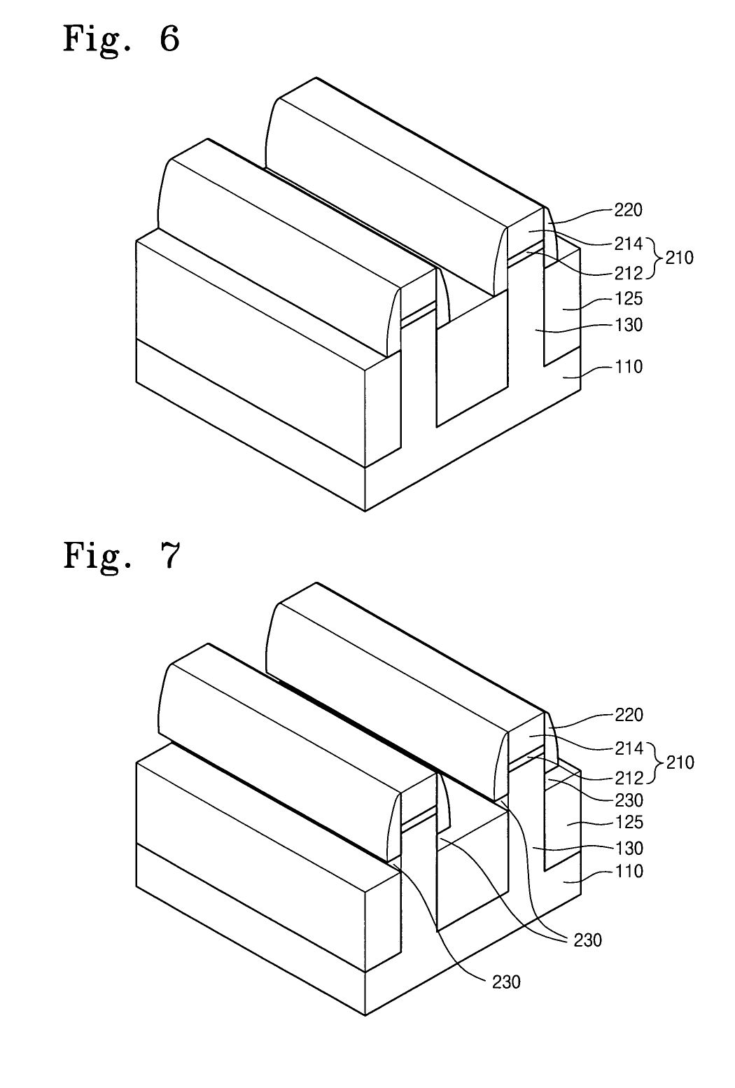

Referring to FIG. 6, a spacer 220 may be formed on the exposed upper sidewalls of the preliminary semiconductor pin 130 and the sidewalls of the mask 210. The spacer 220 may be formed by forming a spacer layer on a surface, e.g., an entire surface, of the semiconductor substrate 110, and then, etching back the formed spacer layer. As described below, in some embodiments of the invention, the spacer 220 may include a material having an etch selectivity with regard to the device isolation layer pattern 125. For example, when the device isolation layer pattern 125 is formed of silicon oxide, the spacer 220 may include silicon nitride.

Referring to FIG. 7, an etch process may be performed to recess, i.e., remove an upper portion of, the device isolation layer pattern 125 and to form an undercut 230. The undercut 230 may partially expose the sidewalls of the preliminary semiconductor pin 130 below the spacer 220. In some embodiments, the device isolation layer pattern 125 may be recessed using an etch recipe having an etch selectivity with regard to the spacer 220. Also, in some embodiments of the invention, an anisotropic etching method may be employed to form the undercut 230 below the spacer 220.

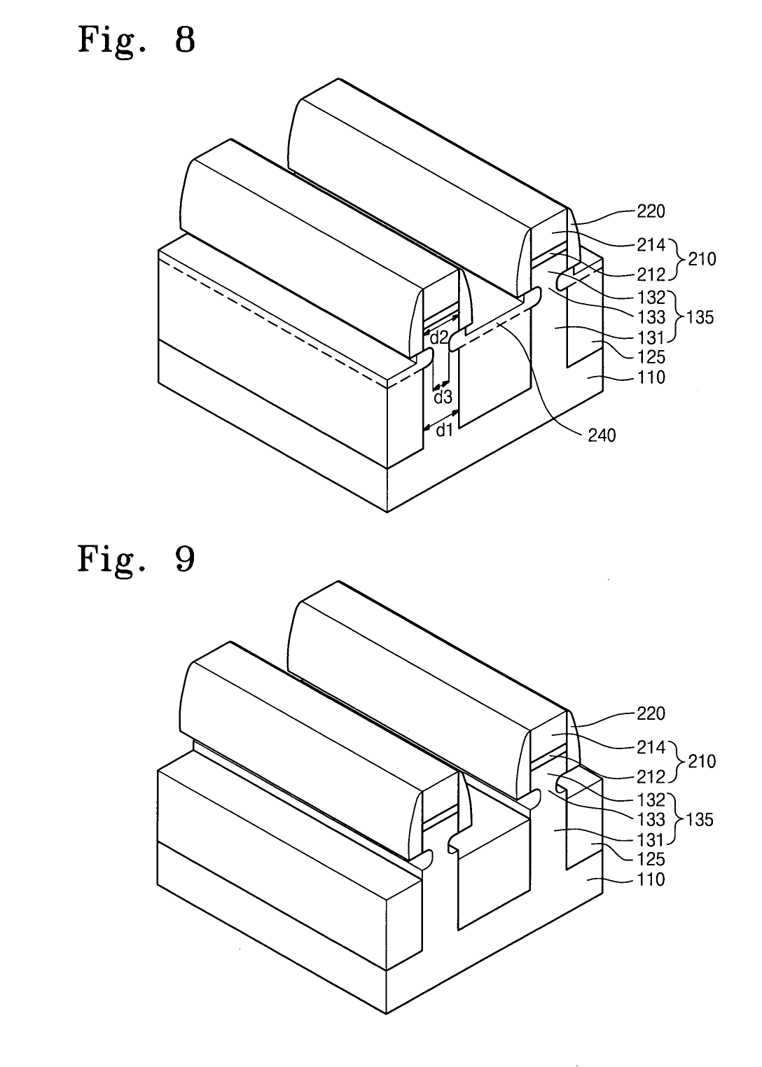

Referring to FIG. 8, a thermal oxidation process may be performed to form a sacrificial oxide layer 240 on the exposed sidewalls of the preliminary semiconductor pin 130 and the device isolation layer pattern 125. By the thermal oxidation process, the exposed sidewalls of the preliminary semiconductor pin 130 may be transformed into an oxide layer and a width of the exposed portions of the preliminary semiconductor pin 130 may be decreased. That is, in embodiments of the invention, a semiconductor pin 135 may be formed from the preliminary semiconductor pin 130 by the thermal oxidation process.

The semiconductor pin 135 may be divided into three portions, i.e., the third semiconductor pattern 133 corresponding to the portion of the preliminary semiconductor pin 130 that was narrowed by the thermal oxidation process, the first semiconductor pattern 131 disposed therebelow and connected with the semiconductor substrate 110, and a second semiconductor pattern disposed on the third semiconductor pattern 133 and contacting the mask 210. That is, the semiconductor pin 135 may be designed such that the first semiconductor pattern 131 and the second semiconductor pattern 132 are connected with each other by the third semiconductor pattern 133 located therebetween. In some embodiments, the width d1 of the first semiconductor pattern 131 may be equal to the width d2 of the second semiconductor pattern 132, and the widths d1 and d2 may be larger than the width d3 of the third semiconductor pattern 133.

Referring to FIG. 9, an etch process may be performed to remove the sacrificial oxide layer 240 and to expose the third semiconductor pattern 133. At this stage, the device isolation layer pattern 125 may be overetched to partially expose an upper portion of sidewalls of the first semiconductor pattern 131. During the etching process for removing the sacrificial oxide layer 240, the sacrificial oxide layer 240 may be removed using an etch recipe having an etch selectivity with regard to the spacer 220. In some embodiments of the invention, an isotropic etching method may be employed to remove the sacrificial oxide layer 240 formed on the sidewalls of the third semiconductor pattern 133.

To form the third semiconductor pattern 133, some embodiments of the invention may employ the method of forming the sacrificial oxide layer and removing the same. However, embodiments of the invention are not limited to such a method. For example, in other embodiments of the invention, again referring to FIG. 7, the third semiconductor pattern 133 may be formed by forming the undercut 230 partially exposing the sidewalls of the preliminary semiconductor pin 130 below the spacer 220 and removing a portion of the exposed sidewalls of the preliminary semiconductor pin 130 by performing an etch process.

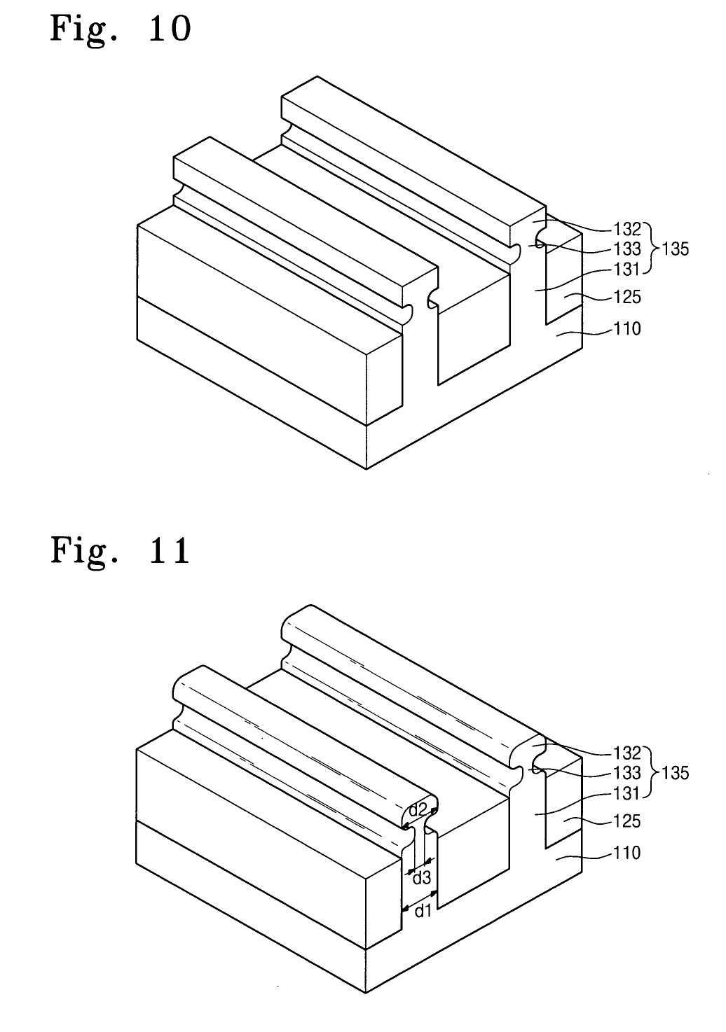

Referring to FIG. 10, an etch process may be performed to remove the mask 210 and the spacer 220, and expose the second semiconductor pattern 132. Thereafter, a channel ion implantation process may be performed. The impurity ions (not shown) may then be implanted by, e.g., an inclined ion implantation method. In some embodiments of the invention, the channel ion implantation process may be performed prior to the impurity ion implantation process. For example, again referring to FIG. 6, impurity ions may be implanted into the exposed upper sidewalls of the preliminary semiconductor pin 130 before forming the spacer 220.

Referring to FIG. 11, a process (hereinafter referred to as “rounding process”) for rounding edges of the second semiconductor pattern 132 may be performed. For example, the rounding process may be performed by performing a thermal oxidation process, and then, performing a cleaning process or a hydrogen annealing process. By doing so, the second semiconductor pattern 132 may have a cylindrical shape. As discussed above, a cross-section of the second semiconductor pattern 132 may have, e.g., a circular or elliptical shape.

The width d2 of the second semiconductor pattern 132 and the width d3 of the third semiconductor pattern 133 may be decreased by the rounding process. In other words, a size of the second semiconductor pattern 132 may be set by the rounding process. The size of the second semiconductor pattern 132 may be determined considering an intensity and distribution of a threshold voltage required by the memory device.

By rounding edges of the second semiconductor pattern 132 using the rounding process, a parasitic capacitance that may be generated at a sharp or pointed portion may be reduced or eliminated, and in a subsequent process, the tunneling insulation layer 140 may be conformally formed.

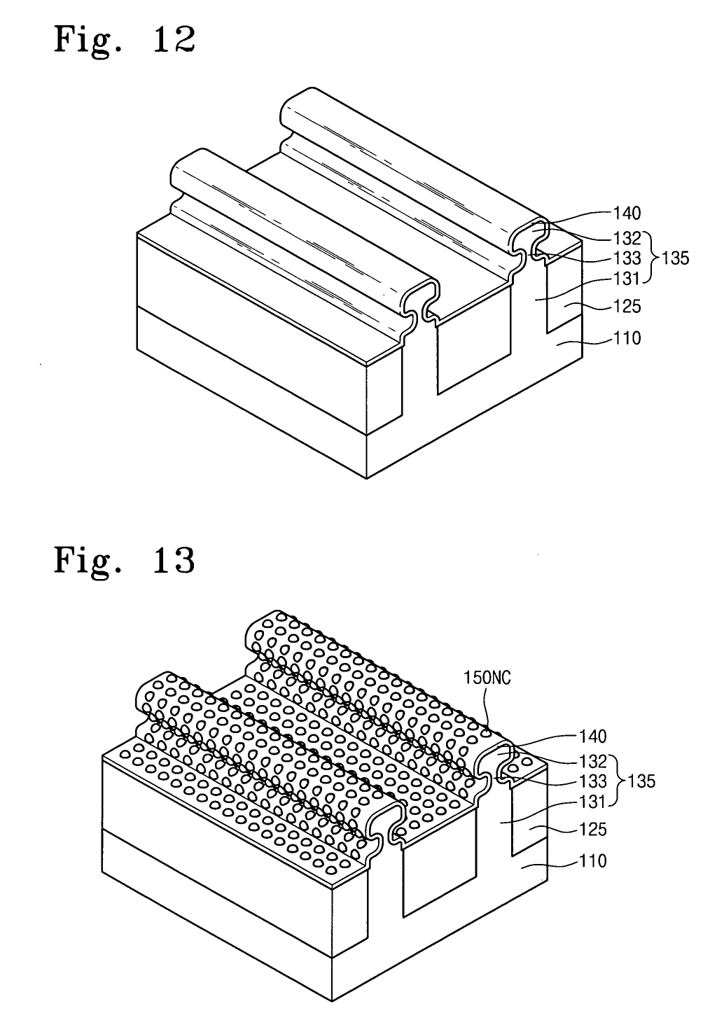

Referring to FIG. 12, the tunneling insulation layer 140 may be conformally formed on the surface, e.g., an entire surface, of the semiconductor substrate 110. The tunneling insulation layer 140 may include, e.g., silicon oxide and may be formed using, e.g., a well known thin film forming process, e.g., a thermal oxidation process.

Referring to FIG. 13, nanocrystals 150NC may be formed on the tunneling insulation layer 140. The nanocrystals 150NC may include, e.g., nitride, oxide, silicon, silicon-germanium and/or metal material. The respective nanocrystals 150NC may be spaced apart from one another. That is, in some embodiments, a predetermined distance may exist between respective nanocrystals 150NC.

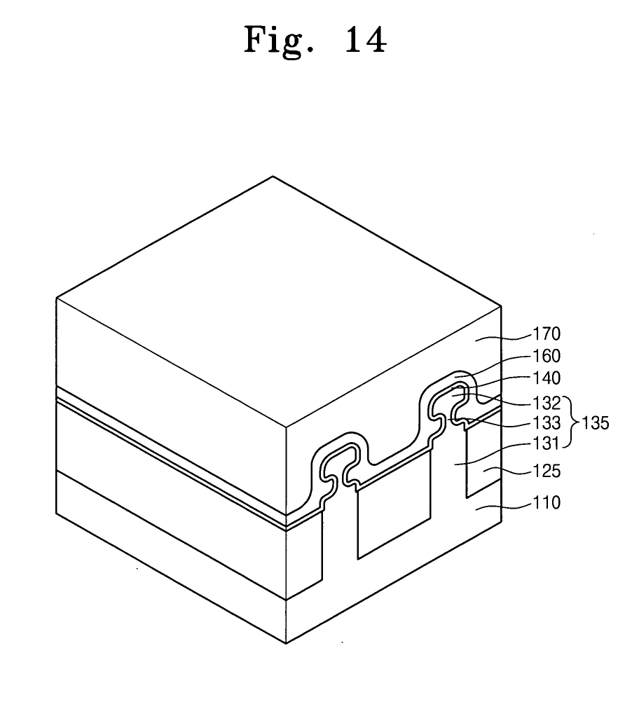

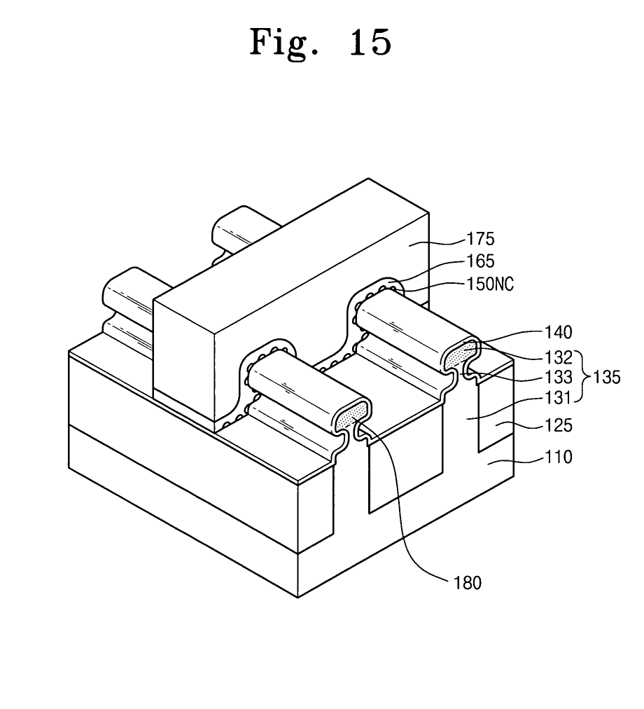

Referring to FIG. 14, a preliminary blocking insulation layer 160 and a gate conductive layer 170 may be formed on the charge storage layer 150 (see FIG. 13). The preliminary blocking insulation layer 160 may include, e.g., oxide. In some embodiments of the invention, the preliminary blocking insulation layer 160 may include, e.g., an insulation material having a high dielectric constant, e.g., aluminum oxide (Al₂O₃), hafnium oxide (HfO), hafnium aluminum oxide (HfAlO), hafnium silicon oxide (HfSiO) and the like. The gate conductive layer 170 may include conductive material, e.g., doped polysilicon and/or metal.

Referring to FIG. 15, a photolithography process and an etch process may be performed to form a blocking insulation layer 165 and a gate electrode 175. During such an etch process, the gate conductive layer 170, the preliminary blocking insulation layer 165 and the nanocrystals 150NC may be etched using the tunneling insulation layer 140 as an etch stop layer. The gate electrode 175 may be formed so as to extend in the second direction crossing the first direction. As discussed above, the first direction may be perpendicular to the second direction. The respective nanocrystals 150NC may be insulated from each another by the blocking insulation layer 165 filled therebetween.

Thereafter, an ion implantation process may be performed to form an impurity region (or junction region) 180 corresponding to source/drain regions in the second semiconductor pattern 132. The impurity regions 180 corresponding to the source/drain regions may be formed at both sides of the gate electrode 175.

Embodiments of the invention enable highly integrated devices having desired threshold voltage characteristics, e.g., a desired threshold voltage and distribution to be provided adjusting or setting a size of the second semiconductor pattern.

In embodiments of the invention, because the tunneling insulation layer may overlap the channel region, the channel may be better controlled by the gate electrode.

In embodiments of the invention, by providing a semiconductor pattern with rounded edges of respective portions corresponding to the impurity regions, parasitic capacitance may be suppressed and/or eliminated.

Embodiments of the invention provide nonvolatile memory devices having improved reliability and improved operating characteristics.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A nonvolatile memory device, comprising:
a semiconductor pin including a first semiconductor pattern, a second semiconductor pattern on the first semiconductor pattern, and a third semiconductor pattern, disposed between the first semiconductor pattern and the second semiconductor pattern, connecting the first semiconductor pattern and the second semiconductor pattern;
a charge storage layer on the second semiconductor pattern with a tunneling insulation layer interposed therebetween; and
a gate electrode on the charge storage layer with a blocking insulation layer interposed therebetween,
wherein a width of the second semiconductor pattern is greater than a width of the third semiconductor pattern.

2. The nonvolatile memory device as claimed in claim 1, wherein the first semiconductor pattern is a portion of a semiconductor substrate on which the nonvolatile memory device is formed and/or is connected to and/or extends from the semiconductor substrate.

3. The nonvolatile memory device as claimed in claim 1, wherein the charge storage layer includes nanocrystals.

4. The nonvolatile memory device as claimed in claim 1, wherein a width of the first semiconductor pattern is greater than the width of the second semiconductor pattern along a direction along which the gate electrode extends.

5. The nonvolatile memory device as claimed in claim 1, wherein the second semiconductor pattern has a circular or elliptical cross-sectional shape.

6. The nonvolatile memory device as claimed in claim 1, wherein the second semiconductor pattern has a cylindrical shape and extends in a direction crossing the direction along which the gate electrode extends.

7. The nonvolatile memory device as claimed in claim 1, further comprising a channel region and source/drain regions, wherein the channel region and the source/drain regions are disposed in the second semiconductor pattern.

8. The nonvolatile memory device as claimed in claim 1, wherein other than a portion of the second semiconductor pattern that contacts the third semiconductor pattern, the second semiconductor pattern is substantially surrounded by a gate insulating layer.

9. The nonvolatile memory device as claimed in claim 1, further comprising a device-isolation layer pattern disposed at both sides of the semiconductor pin, the device-isolation layer defining the semiconductor pin as an active region, wherein an upper surface of the device-isolation layer pattern is disposed under the third semiconductor pattern.

10. A method for forming a nonvolatile memory device, the method comprising:
forming a semiconductor pin including a first semiconductor pattern, a second semiconductor pattern on the first semiconductor pattern, and a third semiconductor pattern, disposed between the first semiconductor pattern and the second semiconductor pattern, connecting the first semiconductor pattern and second semiconductor pattern;
forming a tunneling insulation layer on the second semiconductor pattern;
forming a charge storage layer on the tunneling insulation layer;
forming a blocking insulation layer on the charge storage layer; and
forming a gate electrode extending on the blocking insulation layer in a direction crossing a direction along which the semiconductor pin extends,
wherein a width of the second semiconductor pattern is greater than a width of the third semiconductor pattern.

11. The method as claimed in claim 10, wherein the width of the first semiconductor pattern is greater than the width of the second semiconductor pattern along a direction in which the gate electrode extends.

12. The method as claimed in claim 10, wherein forming the semiconductor pin comprises:
forming a preliminary semiconductor pin connected to the semiconductor substrate and having a substantially uniform width;
forming a device-isolation layer pattern disposed on sides of the preliminary semiconductor pin, a portion of the preliminary semiconductor pin protruding beyond an upper surface of the device-isolation layer pattern;
forming a spacer on a protruding portion of an upper sidewall of the preliminary semiconductor pin;
recessing the device-isolation layer pattern to expose a portion of the preliminary semiconductor pin;
removing a portion of the exposed preliminary semiconductor pin to reduce a width thereof.

13. The method as claimed in claim 12, wherein reducing the width of the exposed preliminary semiconductor pin comprises:
performing an oxidation process on the exposed preliminary semiconductor pin to form a sacrificial oxide layer reducing the width of the preliminary semiconductor pin; and
performing an isotropic etching process to remove the sacrificial oxide layer.

14. The method as claimed in claim 13, wherein the oxidation process is a thermal oxidation process, and the sacrificial oxide layer is a thermal oxide layer.

15. The method as claimed in claim 12, further comprising removing the spacer and performing an isotropic etching process after removing the spacer to form the second semiconductor pattern having a cylindrical shape.

16. The method as claimed in claim 10, wherein forming the preliminary semiconductor pin comprises:
forming a mask pattern on semiconductor substrate, the mask pattern corresponding to a region where the semiconductor pin is to be formed;
etching the semiconductor substrate using the mask pattern as an etch mask to form a trench; and
forming a device-isolation layer filling the trench.

17. The method as claimed in claim 10, wherein the spacer is formed of a material having an etch selectivity with regard to the device-isolation layer.

18. The method as claimed in claim 10, further comprising performing a channel ion implantation process on the second semiconductor pattern before forming the tunneling insulation layer.

19. The method as claimed in claim 10, wherein forming the charge storage layer comprises forming nanocrystals on the tunneling insulation layer.

20. The method as claimed in claim 10, further comprising performing an ion implantation process to form a source/drain region in the second semiconductor pattern after forming the gate electrode.
